(19) United States
(12) Patent Application Publication
(10) Pub. No.: US 2001/0003051 A1
(43) Pub. Date: Jun. 7, 2001

(54) Semiconductor integrated circuit, semiconductor integrated circuit manufacturing method and semiconductor integrated circuit test method

(75) Inventor: Yutaka Yoshizawa, Tokyo (JP)

Correspondence Address: HELFGOTT & KARAS P.C., 60th Floor, Empire State Building, New York, NY, 10118-0110, US

(73) Assignee: NEK CORPORATION

(21) Appl. No.: 09/731,218

(22) Filed: Dec. 6, 2000

(30) Foreign Application Priority Data
Dec. 7, 1999 (JP) 11-348160

(51) Int. Cl. G11C 7/00

(52) U.S. Cl. 438/257; 365/201

(57) ABSTRACT

The invention provides a semiconductor integrated circuit of good quality, a manufacturing method for manufacturing such a semiconductor integrated circuit and a test method thereof.

A semiconductor integrated circuit 1 is provided with a logic circuit 2 connected to external terminals 10 through 12, a built-in memory 3 connected to this logic circuit, and a burn-in test circuit 4 for, when performing burn-in test of this built-in memory, writing predetermined data into the built-in memory.

### BACKGROUND OF THE INVENTION

1. Field of the Invention

The present invention relates to a semiconductor integrated circuit (system LSI) that has memory, for example DRAM (dynamic random access memory), and a microcomputer or a logic circuit built in. The invention relates to a structure for testing built-in memory externally.

Furthermore, the present invention relates to a memory, for example DRAM (dynamic random access memory), a test circuit having a function of testing this memory, and a semiconductor integrated circuit (system LSI) having a microcomputer or a logic circuit built-in.

Moreover, the present invention relates to a semiconductor integrated circuit (system LSI), wherein SDRAM (Synchronous dynamic random access memory), which operates with a synchronizing clock signal, is used for DRAM.

Furthermore, the present invention relates to a manufacturing method and a test method of such a semiconductor integrated circuit (system LSI), and in particular relates to a burn-in test and a built-in self test for memory which is built into such a semiconductor integrated circuit (system LSI).

2. Description of the Related Art

With the development of semiconductor integrated circuits, that is, densification and high integration, so-called system LSI, wherein a plurality of function blocks is integrated in one chip, has become remarkably widespread. In particular, system LSI where logic circuits and memory, for example DRAM, are both included in one chip has recently attracted attention.

With such system LSI, wherein logic circuits and memory are built-in, since it is possible to shorten the wires between the logic circuits and the memory, parasitic capacitance and resistance of the wires can be reduced. Hence data can be transferred with high speed. Furthermore, since the logic circuits and the memory, which are connected only by internal wires, do not go by way of external terminals, the data bus for connection can be widened to increase the bit-width of transfer data, hence enabling the transfer of data at high speed.

Accompanying the spread of such system LSI, testing of each function block at the time of manufacture of the system LSI is also becoming more important.

FIG. 24 shows a schematic diagram of a system LSI wherein conventional DRAM is built in. This system LSI 101 has built-in a regular circuit 102 comprising a microcomputer or a logic circuit, and a built-in DRAM 103. The regular circuit 102 operates corresponding to a clock signal CLK input from a CLK terminal 113 of the system LSI 101, and a reset signal RST input from a RESET terminal 114, performs a predetermined process followed by instructions from an IN terminal 110, an I/O terminal 112, and the like, outputs a predetermined signal from an OUT terminal 111, and accesses the built-in DRAM 103.

A functional test for the built-in DRAM 103 built into such a system LSI 101, since terminals 103a, 103b and 103c are not directly drawn to the outside of the system LSI 101, is performed via the regular circuit 102. That is to say, an instruction for performing a functional test is transmitted to the regular circuit 102 from an external terminal, for example the IN terminal 110, the regular circuit 102 transmits a control signal for performing the functional test to the built-in DRAM 103, and the result of the functional test is read out from an external terminal, for example the OUT terminal 111, via the regular circuit 102 again.

Furthermore, the system LSI shown in FIG. 25 is disclosed in Japanese Unexamined Patent Application, First Publication No. 11-260096. In this system LSI 101, selectors 105, 118, and 106 are provided between the regular circuit 102 and the built-in DRAM 103, and the arrangement is such that these selectors are switched by a mode signal input from a TEST terminal 109, enabling access to the built-in DRAM 103 directly from an external terminal of the system LSI 101.

With the conventional technique shown in FIG. 24, it is not possible to perform the same test for memory built into the system LSI as for general memory at the time of manufacture. Therefore, there is a problem in that the same quality cannot be guaranteed for the memory built into the system LSI as for the general memory. This is because this system LSI cannot allow direct access from an external terminal to the built-in memory.

For a specific example of the abovementioned test, there is a test in which data is written into each memory cell, the written data is read out, and it is checked whether the same data as was written is read out, and a test in which each address in the memory is stepped through, while data is written into each address, and the written data is read out. This is because the memory is composed of a circuit for selecting the address, and memory cells for memorizing data, and hence it is necessary to test that both operate normally.

However, as in the abovementioned system LSI, if direct access to the built-in memory from external terminals is not possible, addresses in the built-in memory cannot be directly assigned. Therefore, there is a case where no address of the built-in memory can be assigned. As a result, the same test as for the general memory cannot be performed on the memory built into the system LSI, and hence the same quality as for the general memory cannot be guaranteed.

Furthermore, there is a problem in that an expensive dynamic BT (Burn-in Test) system is required for dynamic BT of the memory built into the system LSI.

The dynamic BT system will now be described. The dynamic BT system has an oven for maintaining the system LSI at a constant temperature, and a pattern generator for generating patterns. There are many kinds of memory that can be tested by this dynamic BT system; for DRAM there are conventional DRAM and SDRAM for example, and furthermore the SDRAM could have a variety of sizes. Since the dynamic BT system for testing these memories, which is a system to be incorporated into a memory sorting line, has to be compatible with all kinds and sizes of memory, the pattern generator becomes very complicated. Consequently, the dynamic BT system is expensive.

Heretofore, a clocked BT system has normally been used to test system LSI. Accordingly, to use a dynamic BT system for the system LSI, a new investment is required.

Furthermore, in the case of a conventional technique shown in FIG. 25, by switching a selector, a terminal of a memory (built-in DRAM) is connected to an external terminal of the system LSI, and the memory is directly accessed from the external terminal so that this memory can be tested. However, since the external terminal remains connected to the logic circuit (a regular circuit) even when performing the test, the current consumption of only the memory (built-in DRAM), for example, cannot be tested correctly.

Moreover, since the abovementioned system LSI includes both a logic circuit (regular circuit) and memory (built-in DRAM), to test this system LSI, two test processes; a process for testing the logic circuit using a logic circuit tester and a process for testing the memory using a memory tester are required. Therefore, there is a problem in that it takes a lot of time to test.

To be specific, wafer test of the system LSI requires two processes, a wafer test for the memory and a wafer test for the logic circuit. Here, the wafer test is one part of the manufacturing process of the system LSI, and is for testing whether each chip operates normally before being separated, by probing the wafer after it has finished diffusing and using an LSI tester, while it is still in the wafer condition.

Moreover, there is a problem in that when a selector is added afterwards to a circuit that performs normal processing, signal timing in normal processing is changed. This is because the propagation delay time of the signal is changed due to the selector insertion or rewiring in the vicinity of the selector, which causes a change in signal timing. Consequently, there is a possibility that the circuit, which had completed timing design before the selector insertion, needs to be redesigned.

### SUMMARY OF THE INVENTION

The present invention is aimed at solving the abovementioned problems, to provide a semiconductor integrated circuit (system LSI) of good quality, a manufacturing method for manufacturing such a semiconductor integrated circuit (system LSI) and a test method thereof.

A first aspect of the invention is a semiconductor integrated circuit characterized in having a logic circuit connected to external terminals, built-in memory connected to this logic circuit, and a burn-in test circuit for, when performing burn-in test of this built-in memory, writing predetermined data into the built-in memory.

With the abovementioned construction, the burn-in test circuit automatically writes data into all memory cells of the built-in memory sequentially by only clock input from a clock input terminal of the semiconductor integrated circuit, and reset signal input from a reset terminal thereof.

A second aspect of the invention is a semiconductor integrated circuit characterized in having a logic circuit connected to external terminals, built-in memory connected to this logic circuit, and a built-in self test circuit for, when performing built-in self test of this built-in memory, writing predetermined data into the built-in memory, reading out the written data from the built-in memory, comparing the written data with the read out data, and judging whether the built-in memory is normal.

With the abovementioned construction, the built-in self test circuit automatically writes data into all memory cells of the built-in memory sequentially by only clock input from the clock input terminal of the semiconductor integrated circuit, and reset signal input from the reset terminal thereof, reads the written data sequentially, and judges whether the written data is the same data as the read out data.

A third aspect of the invention is a semiconductor integrated circuit characterized in having a logic circuit connected to external terminals, built-in memory connected to this logic circuit, a burn-in self test circuit for, when performing burn-in self test of the built-in memory, writing predetermined data into the built-in memory, and a built-in self test circuit for, when performing built-in self test of the built-in memory, writing predetermined data into the built-in memory, reading out the written data from the built-in memory, comparing the written data with the read out data, and judging whether the built-in memory is normal.

A fourth aspect of the invention is a semiconductor integrated circuit according to the third aspect, which is characterized in that the burn-in test circuit and built-in self-test circuit are formed in one test circuit cell.

A fifth aspect of the invention is a semiconductor integrated circuit having; a logic circuit connected to external terminals via a first selector, and built-in memory connected to this logic circuit via a second selector, characterized in that; the first selector selects whether to connect the external terminals either to the logic circuit, or to the second selector, and the second selector selects whether to connect the built-in memory either to the logic circuit or to the first selector.

With the abovementioned construction, in a semiconductor integrated circuit that has memory built in, by switching the selectors, it is possible to access each terminal in the built-in memory directly from the external terminals of the semiconductor integrated circuit. Therefore, it is possible to test the built-in DRAM by direct operation from the external terminals of the semiconductor integrated circuit. Furthermore, since first selectors are provided, at the time of testing the built-in memory it is possible to completely separate the logic circuit (regular circuit) from the external terminals of the semiconductor integrated circuit.

A sixth aspect of the invention is a semiconductor integrated circuit according to the fifth aspect, characterized in having a burn-in test circuit for, when performing burn-in test of the built-in memory, writing predetermined data into the built-in memory.

A seventh aspect of the invention is a semiconductor integrated circuit according to the fifth aspect, characterized in having a built-in self test circuit for, when performing a built-in self test of the built-in memory, writing predetermined data into the built-in memory, reading out the written data from the built-in memory, comparing the written data with the read out data, and judging whether the built-in memory is normal.

An eighth aspect of the invention is a semiconductor integrated circuit according to the fifth aspect, characterized in having a burn-in test circuit for, when performing burn-in test of the built-in memory, writing predetermined data into the built-in memory, and a built-in self test circuit for, when performing built-in self test of the built-in memory, writing predetermined data into the built-in memory, reading out the written data from the built-in memory, comparing the written data with the read out data, and judging whether the built-in memory is normal.

A ninth aspect of the invention is a semiconductor integrated circuit according to any one of the first to eighth aspects, characterized in that the built-in memory is DRAM.

A tenth aspect of the invention is a semiconductor integrated circuit according to the ninth aspect, characterized in that the DRAM is SDRAM, and the SDRAM has built in, a mode register for setting the operation mode of the SDRAM and a mode register automatic setting circuit for automatically setting the mode register corresponding to an input from the external terminals.

With the abovementioned construction, since DRAM built into the semiconductor integrated circuit is SDRAM, and a mode register automatic setting circuit is built into this SDRAM, when the semiconductor integrated circuit enters BT mode or BIST mode, the mode register of the SDRAM is automatically set to a predetermined value.

An eleventh aspect of the invention is a semiconductor integrated circuit according to any one of the fifth aspect to the eighth aspect, characterized in that the first selector, and an input buffer or an output buffer connected to the external terminals, are contained in an I/O cell, and the second selector and the built-in memory are contained in a built-in memory cell.

With the abovementioned construction, even when a test circuit is added to the circuit for normal processing, the time delay does not change.

A twelfth aspect of the invention is a semiconductor integrated circuit manufacturing method, characterized in that an I/O cell and a built-in memory cell according to the eleventh aspect are used in the design.

A thirteenth aspect of the invention is a semiconductor integrated circuit test method, characterized in that a semiconductor integrated circuit according to any one of the first aspect to the eleventh aspect is used.

A fourteenth aspect of the invention is a semiconductor integrated circuit manufacturing method, characterized in that a test method according to the thirteenth aspect is used.

### BRIEF DESCRIPTION OF THE DRAWINGS

FIG. 1 is a block diagram of a system LSI having DRAM built in, of a first embodiment of the present invention.

FIG. 2 is a block diagram of a system LSI having DRAM built in, of a second embodiment of the present invention.

FIG. 3 is a block diagram of a system LSI having DRAM built in, of a third embodiment of the present invention.

FIG. 4 is a block diagram of a system LSI having DRAM built in, of a fourth embodiment of the present invention.

FIG. 5 is a block diagram of a system LSI having DRAM built in, of a fifth embodiment of the present invention.

FIG. 6 is a block diagram of a system LSI having DRAM built in, of a sixth embodiment of the present invention.

FIGS. 7A to 7C show specific structures of each selector used in the sixth embodiment.

FIGS. 8A to 8C show specific structures of each selector used in the sixth embodiment.

FIGS. 9A to 9C show specific structures of each selector used in the sixth embodiment.

FIG. 10 shows a specific structure of each selector used in the sixth embodiment.

FIGS. 11A to 11C show specific structures of each selector used in the sixth embodiment.

FIGS. 12A to 12C show specific structures of each selector used in the sixth embodiment.

FIGS. 13A to 13C show specific structures of each selector used in the sixth embodiment.

FIGS. 14A to 14C show specific structures of each selector used in the sixth embodiment.

FIGS. 15A to 15C show specific structures of each selector used in the sixth embodiment.

FIG. 16 shows a specific structure of each selector used in the sixth embodiment.

FIG. 17 is a timing diagram of initialization setting operations after power up.

FIG. 18 is a timing diagram of data writing and reading out operations after the initialization is completed.

FIG. 19 is a block diagram of built-in DRAM (SDRAM) that a mode register automatic setting circuit 3e of the present invention is built into.

FIG. 20 is a block diagram of a system LSI having DRAM built in, of a seventh embodiment of the present invention.

FIG. 21 is a conceptual diagram of delay design.

FIG. 22 is a conceptual diagram in which a test circuit including selectors 20, 21, 18 and 5 is added to a circuit, whose circuit design under regular operating conditions has been completed, by conventional techniques.

FIG. 23 is a conceptual diagram in which a test circuit including selectors 20, 21, 18 and 5 is added to a circuit, whose circuit design under regular operating conditions has been completed, by the present invention.

FIG. 24 shows a structure of a conventional system LSI having DRAM built in.

FIG. 25 shows a structure of a conventional system LSI having DRAM built in.

### DETAILED DESCRIPTION OF THE INVENTION

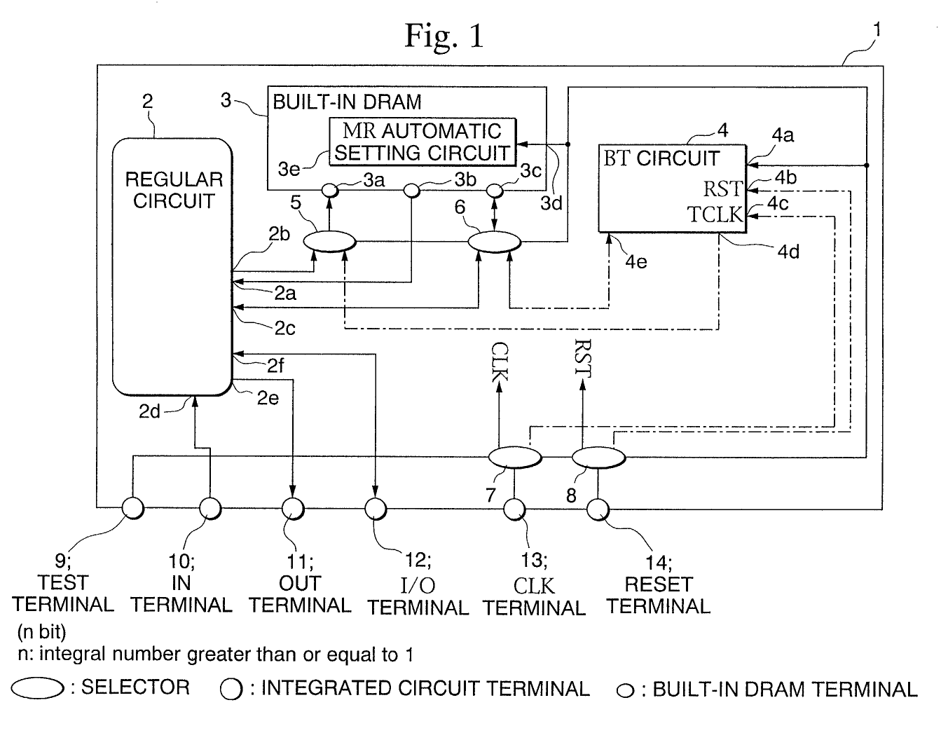

FIG. 1 is a block diagram of a system LSI having built-in DRAM of a first embodiment of the present invention. A construction of the present embodiment will be described. The system LSI 1 has built-in a regular circuit 2, a built-in DRAM 3, a BT circuit 4, and selectors 5, 6, 7, 8. Furthermore, this system LSI 1 has a TEST terminal 9, an IN terminal 10, an OUT terminal 11, an I/O terminal 12, a CLK terminal 13, and a RESET terminal 14, as external terminals drawn outside this system LSI 1.

The regular circuit 2 is a logic circuit which is designed according to the product to be manufactured by a manufacturer and the like (referred to hereunder as a manufacturer) that manufacture electric products and the like using this system LSI 1, and has an input terminal 2a, an output terminal 2b, an input-output terminal 2c, an input terminal 2d, an output terminal 2e and an input-output terminal 2f. There may be a case where the regular circuit 2 has two or more of each input terminal, output terminal and input-output terminal. However, the arrangement is such that the input terminal 2a, the output terminal 2b, the input-output terminal 2c, the input terminal 2d, the output terminal 2e and the input-output terminal 2f, shown in the figure represent any number of terminals.

The built-in DRAM 3, which is a DRAM (Dynamic Random Access Memory) built into the system LSI 1, has an input terminal 3a, an output terminal 3b, an input-output terminal 3c and a mode signal input terminal 3d. There may be a case where the built-in DRAM has a plurality of input terminals, output terminals and input-output terminals. However, the arrangement is such that the input terminal 3a, the output terminal 3b and the input-output terminal 3c, shown in the figure represents the plurality of terminals. The output terminal 3b of the built-in DRAM 3 is connected to the input terminal 2a of the regular circuit 2.

In the case where the built-in DRAM 3 is SDRAM (Synchronous dynamic random access memory), a mode register automatic setting circuit 3e is provided in this SDRAM. Processing of the case where the built-in DRAM 3 is SDRAM will be described in a sixth embodiment to be mentioned later. This description is also applicable to the present embodiment.

The characteristic of the present embodiment is that a BT circuit 4 is built into the system LSI 1. The BT circuit is a circuit for, when performing burn-in test (Bum in Test; referred to by the abbreviation BT in some cases hereunder), writing data into the built-in DRAM 3, and has a mode signal input terminal 4a, a reset signal input terminal 4b, a clock signal input terminal 4c, an output terminal 4d and an input-output terminal 4e. The mode signal input terminal 4a of the BT circuit 4 is connected to a TEST terminal 9, and receives a mode signal input from this TEST terminal 9.

The burn-in test (BT) will now be described. BT is a test for testing the durability of a system LSI and the like at a constant temperature. BT has a variety of kinds: a simple one, which is often used for logic circuits, is a test where only the LSI is powered up, and is placed in a constant temperature environment. Furthermore, there is a clocked BT where the LSI is powered up to operate only the clock of this LSI. Moreover, a dynamic BT is a test where data is also input into an input terminal that had not been exercised in the clocked BT, for example, an address terminal and a data terminal in DRAM.

When the system LSI 1 of the present embodiment is supplied with only simple signals such as a clock signal and a reset signal from the clocked BT system outside the system LSI 1, the BT circuit 4 inside the system LSI 1 generates complex patterns required for the dynamic BT. However, the patterns produced at this time may be only specific to this system LSI. Therefore the circuit for producing the patterns may be a circuit specific to this system LSI 1, and hence the circuit size is small. Consequently, incorporating this circuit will hardly increase the chip size of the system LSI 1, so that, compared with installing an expensive dynamic BT system for general purpose in the production line, the cost is low.

A selector 5 selects whether to connect the input terminal 3a of the built-in DRAM 3 to the output terminal 2b of the regular circuit 2, or to connect to the output terminal 4d of the BT circuit 4, depending on the mode signal input from the TEST terminal 9 of the system LSI 1.

A selector 6 selects whether to connect the input-output terminal 3c of the built-in DRAM 3 to the input-output terminal 2c of the regular circuit 2, or to connect to the input-output terminal 4e of the BT circuit 4, depending on a mode signal input from the TEST terminal 9 of the system LSI 1.

A selector 7 selects whether to connect the CLK terminal 13 of the system LSI 1 to the clock signal line in this system LSI 1, or to connect to the clock signal input terminal 4c of the BT circuit 4, depending on a mode signal input from the TEST terminal 9 of the system LSI 1.

A selector 8 selects whether to connect the RESET terminal 14 of the system LSI 1 to the reset signal line in this system LSI 1, or to connect to the reset signal input terminal 4b of the BT circuit 4, depending on a mode signal input from the TEST terminal 9 of the system LSI 1.

Next is a description of the connection of the external terminals of the system LSI 1. The TEST terminal 9 is an input terminal, and is connected to the selector 7, the selector 8, the mode signal input terminal 4a of the BT circuit 4, the mode signal input terminal 3d of the built-in DRAM 3, the selector 6 and the selector 5. Each of these structures is controlled by a mode signal input from the TEST terminal 9.

The IN terminal 10 is an input terminal, and is connected to the input terminal 2d of the regular circuit 2. The OUT terminal 11 is an output terminal, and is connected to the output terminal 2e of the regular circuit 2. There may be a case where the system LSI 1 has a plurality of input terminals, output terminals and input-output terminals respectively. However, the arrangement is such that the IN terminal 10, the OUT terminal 11 and I/O terminal 12 shown in the figure represent the plurality of terminals.

Next is a description of the operation of the present embodiment. The system LSI 1 operates corresponding to a clock signal input from the CLK terminal 13 and a reset signal input from the RESET terminal 14. The regular circuit 2 accesses the built-in DRAM 3 to transfer data, also performs predetermined operations corresponding to signals input from the IN terminal 10 and the I/O terminal 12, and outputs a predetermined signal from the OUT terminal 11.

In the case where the burn-in test (BT) is performed for the system LSI 1, this system LSI 1 is placed in an oven at constant temperature, a mode signal showing the BT mode is input to the TEST terminal 9 of the system LSI 1, power supply voltage is applied to a power terminal (not shown in the figure), to power up the system LSI 1, a clock is supplied from the CLK terminal 13, and a reset canceling signal is input from the RESET terminal 14.

When a mode signal indicating the BT mode is input to the TEST terminal 9, the BT circuit 4 inputs this mode signal from the mode signal input terminal 4a, and outputs a pattern for BT (burn-in test). That is to say, the BT circuit 4 outputs a pattern to the built-in DRAM 3 from the output terminal 4d or the input-output terminal 4e, and writes predetermined data into the built-in DRAM 3. At this time, the selector 5 or the selector 6 selects the output from the BT circuit 4 depending on a mode signal input from the TEST terminal 9.

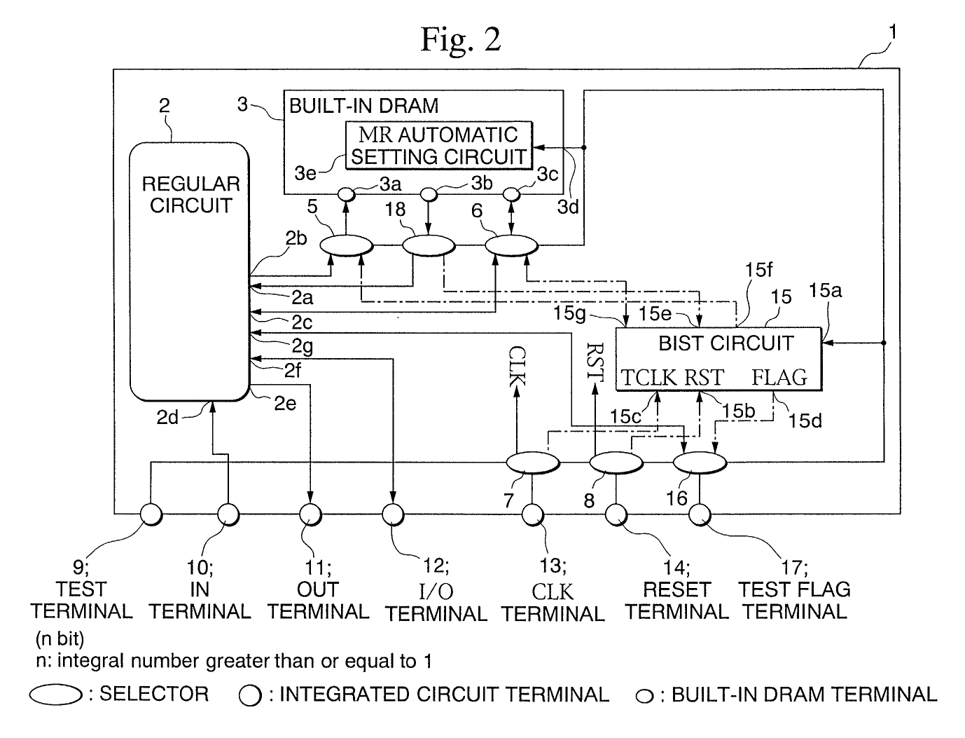

FIG. 2 is a block diagram of a system LSI having DRAM built in of a second embodiment of the present invention. A construction of the present embodiment will now be described. Here, the same symbols are used for the same structures as in the first embodiment, and the description is omitted. This is the same for the embodiments hereunder.

A major difference from the first embodiment is that the present embodiment does not have the BT circuit 4, but has a BIST circuit 15. This BIST circuit 15 is a circuit for, when performing built-in self test (built in self test; abbreviated hereunder to BIST) of the built-in DRAM 3, writing data into the built-in DRAM 3, reading out the data from the built-in DRAM 3, and judging whether the written data and the read out data are the same, and has a mode signal input terminal 15a, a reset signal input terminal 15b, a clock signal input terminal 15c, a FLAG output terminal 15d, an input terminal 15e, an output terminal 15f and an input-output terminal 15g.

The mode signal input terminal 15a of the BIST circuit 15 is connected to the TEST terminal 9 of the system LSI 1, and inputs a mode signal input from this TEST terminal 9. The reset signal input terminal 15b is connected to the selector 8, and this selector 8 selects whether to connect the RESET terminal 14 to a reset signal line inside this system LSI 1, or to connect to the reset signal input terminal 15b, depending on a mode signal input from the TEST terminal 9 of the system LSI 1.

The clock signal input terminal 15c of the BIST circuit 15 is connected to the selector 7. This selector 7 selects whether to connect the CLK terminal 13 of the system LSI 1 to the clock signal line inside this system LSI 1, or to connect to the clock signal input terminal 15c of the BIST circuit 15, depending on a mode signal input from the TEST terminal 9 of the system LSI 1.

The FLAG output terminal 15d of the BIST circuit 15 is connected to a selector 16, and this selector 16 is connected to an output terminal 2g of the regular circuit 2 and also to a TEST FLAG terminal 17 of the system LSI 1. The selector 16 selects either the output from the FLAG output terminal 15d, or output from the output terminal 2g of the regular circuit 2, depending on a mode signal input from the TEST terminal 9 of the system LSI 1.

The output terminal 3b of the built-in DRAM 3 is connected to a selector 18, and the selector 18 is also connected to the input terminal 2a of the regular circuit 2 and the input terminal 15e of the BIST circuit 15.

In the case where the built-in DRAM 3 is SDRAM (Synchronous dynamic random access memory), a mode register automatic setting circuit 3e is provided inside of this SDRAM. Processing of the case where the built-in DRAM 3 is SDRAM will be described in a sixth embodiment to be mentioned later. This description is also applicable to the present embodiment.

Next is a description of the processing of the present embodiment. The processing of the regular circuit 2 and the built-in DRAM 3 is the same as in the first embodiment.

In the case of functional test of the system LSI 1, a mode signal indicating the BIST mode (mode for performing functional test) is input from the TEST terminal 9, power supply voltage is applied to a power terminal (not shown in the figure), to power up the system LSI 1, a clock is supplied from the CLK terminal 13, and a reset canceling signal is input from the RESET terminal 14.

Here, functional test is a test for testing whether the actual output obtained matches the theoretical output for a predetermined input, and is called LFT (Loose Function Test).

When a mode signal showing BIST mode is input from the TEST terminal 9, the BIST circuit 15 performs BIST (built-in self test), in other words, functional self test. That is to say, the BIST circuit 15 outputs a test pattern to the built-in DRAM 3 from the output terminal 15f, writes predetermined data into the built-in DRAM 3, inputs the output from the output terminal 3b of the built-in DRAM 3 from the input terminal 15e, and reads out from the built-in DRAM 3. Furthermore, signals input and output from the input-output terminal 15g of the BIST circuit 15 are input and output to the input-output terminal 3c of the built-in DRAM 3. The BIST circuit 15 compares the data written into the built-in DRAM 3 and the read out data, and judges whether the built-in DRAM 3 is normal. A result of the BIST is output from the FLAG terminal 15d of the BIST circuit 15, and output from the TEST FLAG terminal 17 of the system LSI 1 via the selector 16. A wafer test will now be described. Normally, the manufacturing process of an LSI follows a flow of, wafer test, assembly of the LSI, first sorting by LSI tester, BT (burn-in test), second sorting after BT, and shipping.

Test of the built-in memory of a system LSI that includes both memory and a logic circuit, and that does not have a BIST circuit built in as in the present embodiment is performed using functions that directly access the built-in memory, and the like. However, memory testers and logic circuit testers are completely different systems, and hence the manufacturing process of this system LSI is as follows.

That is to say, wafer test of the logic circuit is performed with a logic circuit tester, wafer test of the built-in memory is performed with a memory tester, the system LSI is assembled, first sorting of the logic circuit is performed, first sorting of the built-in memory is performed, BT (burn-in test) is performed, second sorting of the logic circuit is performed, second sorting of the built-in memory is performed, and shipping is performed. That is to say, there are two parts to each test in the process.

Here, a memory tester generates test patterns for testing memory, reads out the memory output, and compares with the expected value.

As in the present embodiment, if the BIST circuit 15 is built in, a memory tester does not need to be used for test of the built-in memory. This is because part of the function of a memory tester is incorporated in the BIST circuit 15. That is to say, with the logic circuit tester, by testing the logic circuit built into the system LSI 1 and the built-in memory by using the BIST circuit 15 built into this system LSI 1, a test process that uses a memory tester can be omitted, hence enabling functional test with a test process that uses only a logic circuit tester.

Here, functional test in the second test after BT is strictly performed using a memory tester because of the following reason. The memory test requires complex operations. In addition to a test for only writing data into the memory and reading it out, a variety of functions are tested such as operation when an interrupt signal is input, operation when the clock of the memory is masked, refresh operations and the like.

Consequently, it is impossible to incorporate all test functions that the memory tester performs in the BIST circuit 15 built into the system LSI 1 of the present embodiment. Consequently, only a basic test function that can detect the most basic failure, for example a failure such as a poorly formed cell, is incorporated in the BIST circuit 15.

However, if all functions are not tested in the second test, the quality at shipping cannot be guaranteed on a comparable level to the general DRAM. Therefore, in the wafer test, the BIST circuit 15 built into the system LSI 1 is utilized, so that the logic circuit and the memory are tested using the same logic circuit tester to reduce the number of test processes. In the second test, both the logic circuit tester and the memory tester are used to strictly perform testing of the two processes separately. Consequently, only functional test in the wafer test is reduced to one process.

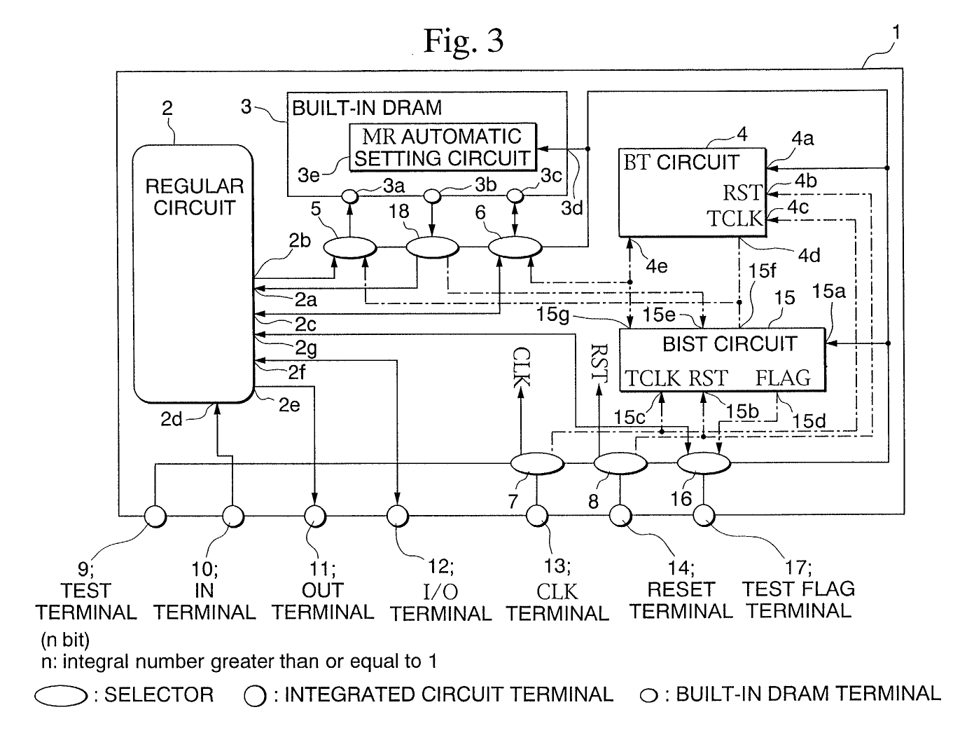

FIG. 3 is a block diagram of a system LSI having built in DRAM of a third embodiment of the present invention. The characteristic of the present embodiment is that both the BT circuit 4 and the BIST circuit 15 are built into the system LSI 1. In this manner, this system LSI 1 can perform both burn-in test (BT) and built-in self test (BIST) by using the built-in circuits.

In the case where the built-in DRAM 3 is SDRAM (synchronous dynamic random access memory), a mode register automatic setting circuit 3e is provided inside of this SDRAM. Processing in the case where the built-in DRAM 3 is SDRAM will be described in a sixth embodiment to be mentioned later. This description is also applicable to the present embodiment.

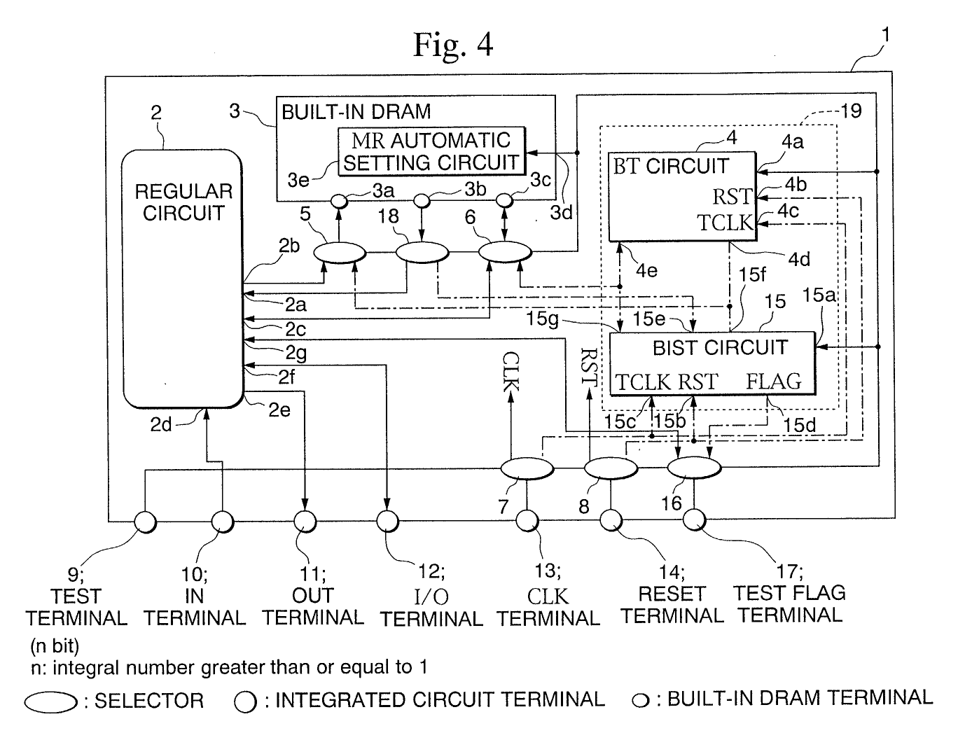

FIG. 4 is a block diagram of a system LSI having built in DRAM of a fourth embodiment of the present invention. The present invention is an example where the BT circuit 4 and the BIST circuit 15 are built into the same test circuit cell 19.

In the case where the built-in DRAM 3 is SDRAM (synchronous dynamic random access memory), a mode register automatic setting circuit 3e is provided inside of this SDRAM. Processing in the case where the built-in DRAM 3 is SDRAM will be described in a sixth embodiment to be mentioned later. This description is also applicable to the present embodiment.

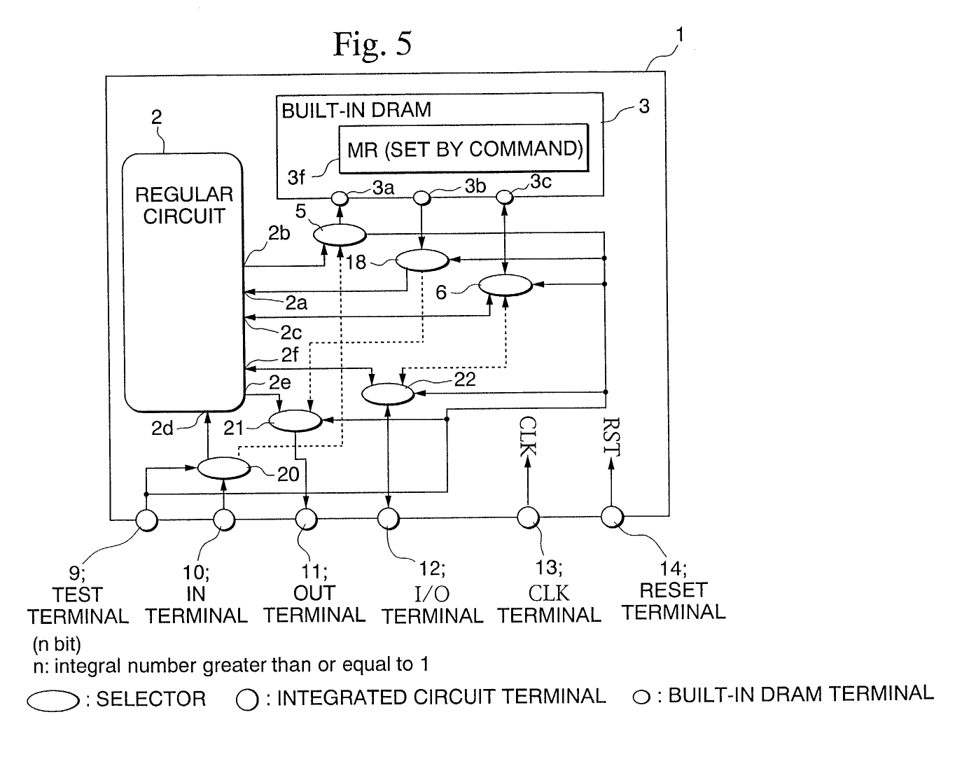

FIG. 5 is a block diagram of a system LSI having built in DRAM of a fifth embodiment of the present invention. The present embodiment includes neither the BT circuit 4 nor the BIST circuit 15, and has selectors in two places inside the system LSI 1. That is to say, in addition to the selectors 5, 18 and 6 connected to the terminals of the built-in DRAM 3, the system has selectors 20, 21 and 22 connected to the external terminals of the system LSI 1.

In the case where the built-in DRAM 3 is SDRAM (synchronous dynamic random access memory), a mode register automatic setting circuit 3e is provided inside of this SDRAM. Processing in the case where the built-in DRAM 3 is SDRAM will be described in a sixth embodiment to be mentioned later. This description is also applicable to the present embodiment.

The selector 20 selects whether to connect the input from the IN terminal 10 to the regular circuit 2, or to the selector 5, depending on a mode signal input from the TEST terminal 9. The selector 21 selects whether to direct the output from the regular circuit 2 or the output from the selector 18 to the OUT terminal 11, depending on a mode signal input from the TEST terminal 9. The selector 22 selects whether to connect the I/O terminal 12 to the regular circuit 2, or to connect to the selector 6, depending on a mode signal input from the TEST terminal 9.

Next is a description of the operation of the present embodiment. When a mode signal showing DRAM direct access mode (mode for directly accessing the built-in DRAM 3 from the external terminals) is input from the TEST terminal 9, the IN terminal 10 is connected to the input terminal 3a of the built-in DRAM 3 via the selector 20 and the selector 5, the OUT terminal 11 is connected to the output terminal 3b of the built-in DRAM 3 via the selector 21 and the selector 18, and the I/O terminal 12 is connected to the input-output terminal 3c of the built-in DRAM 3 via the selector 22 and the selector 6.

In this manner, since it is possible to access the terminals of the built-in DRAM 3 directly from the external terminals of the system LSI 1, test of this built-in DRAM 3 can be performed by directly accessing the built-in DRAM 3.

Moreover, at testing, since the selectors 20, 21 and 22 separate the regular circuit 2 completely from the external terminals of the system LSI 1, the regular circuit 2 has no influence on the testing of the built-in DRAM 3. For example, in the case of measuring current consumption of the built-in DRAM 3, if the regular circuit 2 is connected to the external terminals, the current consumption of the built-in DRAM 3 cannot be measured accurately. However, since the selectors 20, 21 and 22 separate the regular circuit 2 completely from the external terminals of the system LSI 1, the current consumption of the built-in DRAM 3 can be measured accurately.

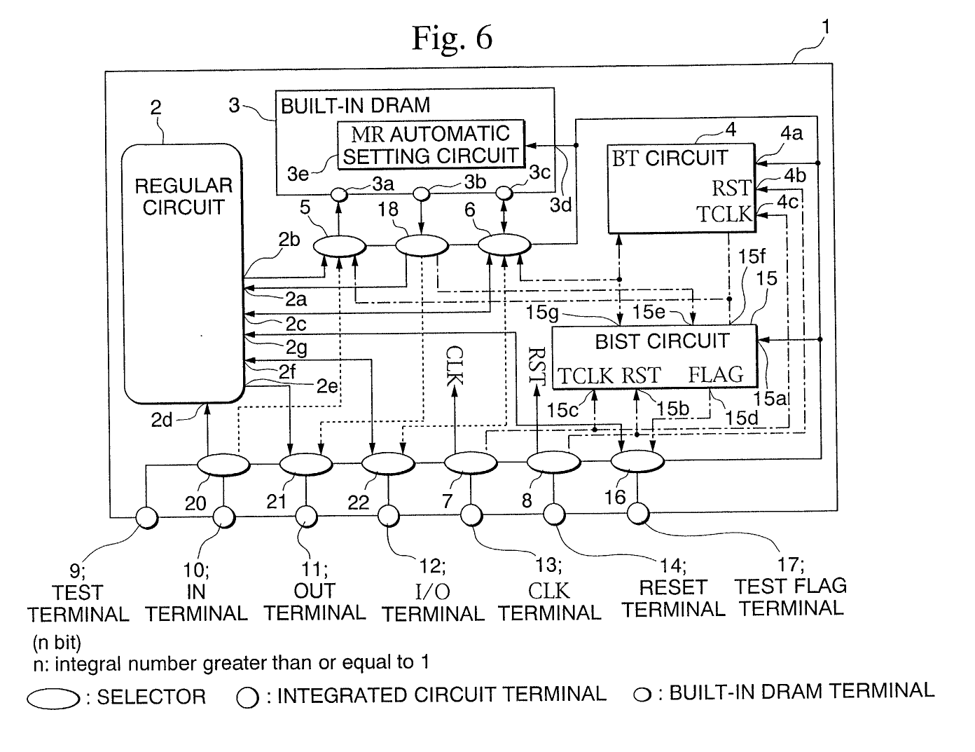

FIG. 6 is a block diagram of a system LSI 1 having built in DRAM of a sixth embodiment of the present invention. The system LSI 1 of the present embodiment has the BT circuit 4, the BIST circuit 15, the selectors 20, 21, and 22 connected to the external terminals of the system LSI 1, and the selectors 5, 18 and 6 connected to the terminals of the built-in DRAM 3, and is provided with a regular operation mode (mode for performing regular operation), DRAM direct access mode (mode for accessing the built-in DRAM 3 directly from the external terminals), BT mode (mode for performing burn-in test by the BT circuit 4), and BIST mode (mode for performing self functional test by the BIST circuit 15) as operation modes.

The structure and operation of the present embodiment will now be described. The solid lines in FIG. 6 are connected at the time of regular operation mode, the broken lines are connected at the time of DRAM direct access mode, and the alternate long and short dashed lines are connected at the time of BIST mode.

The IN terminal 10 represents a plurality of input terminals to the regular circuit 2 (logic circuit). The OUT terminal 11 represents a plurality of output terminals from the regular circuit 2. The CLK terminal 13 is a terminal for inputting a clock signal. The RESET terminal 14 is a terminal for inputting a reset signal. The TEST FLAG terminal 17, which is used as an output terminal of the regular circuit 2 at the time of regular operation mode, is a terminal that outputs a flag showing the test result when in BIST mode.

At the time of regular operation mode, each external terminal of the system LSI 1 is connected to the regular circuit 2, and the regular circuit 2 performs regular operations. Furthermore, any output terminal that a selector has not selected is fixed at H level or L level.

At the time of DRAM direct access mode, that is to say, when the mode allows direct access to the built-in DRAM 3 from the external terminals of the system LSI 1, the broken line in the figure is selected.

At the time of DRAM direct access mode, each external terminal of the system LSI 1 is directly connected to the built-in DRAM 3, so that the built-in DRAM 3 can be directly operated from outside. Consequently, the input from outside of the system LSI 1 via the IN terminal 10 is input directly to the input terminal 3a of the built-in DRAM 3, and the output from the output terminal 3b of the built-in DRAM 3 is output directly to the outside of the system LSI 1 from the OUT terminal 11. The input and output from the I/O terminal 12 are also input and output directly to the input-output terminal 3c of the built-in DRAM 3. Furthermore, any output terminal that a selector has not selected is fixed at H level or L level.

In this way, the built-in DRAM 3 is accessed directly from the outside, hence enabling testing of the built-in DRAM 3.

At the time of BT mode or BIST mode, the selectors 7, 8 and 16 connected to the CLK terminal 13, the RESET terminal 14 and the TEST FLAG terminal 17, and the selectors 5, 18, and 6 connected to the built-in DRAM 3, select signal lines shown by alternate long and short dash lines in the figure. The selectors 20, 21 and 22 select the terminals of the regular circuit 2.

Here, at the time of BT mode, the BIST circuit is halted, and at the time of BIST mode, the BT circuit is halted. This operation is achieved by the mode signal input from the TEST terminal 9 of the system LSI 1 being fed to the mode signal input terminal 4a of the BT circuit 4 and the mode signal input terminal 15a of the BIST circuit 15.

At the time of BT mode, when the reset canceling signal input from the RESET terminal 14 of the system LSI 1, and the clock signal input from the CLK terminal 13 are input to the BT circuit 4, patterns are input to the built-in DRAM 3 from the BT circuit 4, and data is written into each memory cell of the built-in DRAM 3. In this manner, by using the clocked BT system to supply the reset canceling signal and the clock signal, BT (burn-in test) including dynamic BT can be performed.

The procedure of BT (burn-in test) will now be described. Firstly, the system LSI 1 is placed in an oven at a constant temperature, the mode signal to be input from the TEST terminal 9 of the system LSI 1 is determined, the system LSI 1 is powered up, a clock signal is input to the CLK terminal 13, and then, to cancel reset, a reset canceling signal is input from the RESET terminal 14. In this way, BT (burn-in test) is started, DRAM control commands and data are transmitted to the built-in DRAM 3 from the BT circuit 4, and data is written into all cells of the built-in DRAM 3 sequentially. This test is performed continuously, over several hours for example. After a predetermined time has passed, the power to the system LSI 1 is removed to terminate BT (burn-in test).

The BIST (built-in self test) procedure, in other words functional test, will now be described. The DRAM control commands and data are transmitted to the built-in DRAM 3 from the BIST circuit 15. The BIST circuit 15 writes data into all cells of the built-in DRAM 3 sequentially, also reads out the written data concurrently with this writing operation, compares the written data with the read out data, and if there is any mismatch, then it is judged that the built-in DRAM 3 is faulty. The result of the judgment is output from the TEST FLAG terminal 17 of the system LSI 1. This functional test writes data to be written into the built-in DRAM 3, reads out all data to be read out, performs judgment, outputs the judgment result from the TEST FLAG terminal 17, and then terminates.

At this time, the flag output from the TEST FLAG terminal 17 can also be arranged such that, whenever each test item of the functional test is completed, it is output in real time synchronized with the processing of the functional test, or can be also constructed such that it is output when all functional tests are completed.

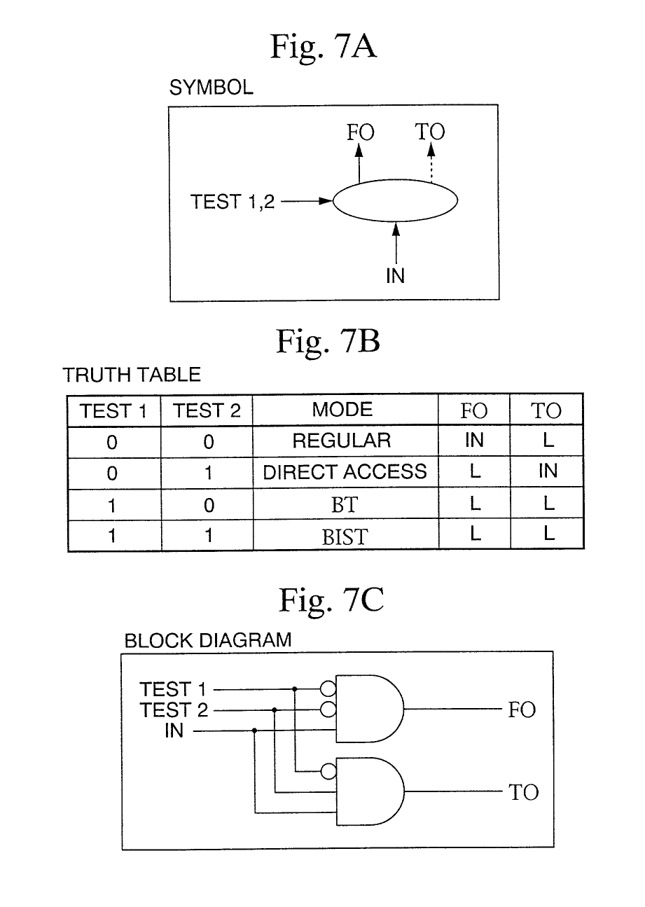

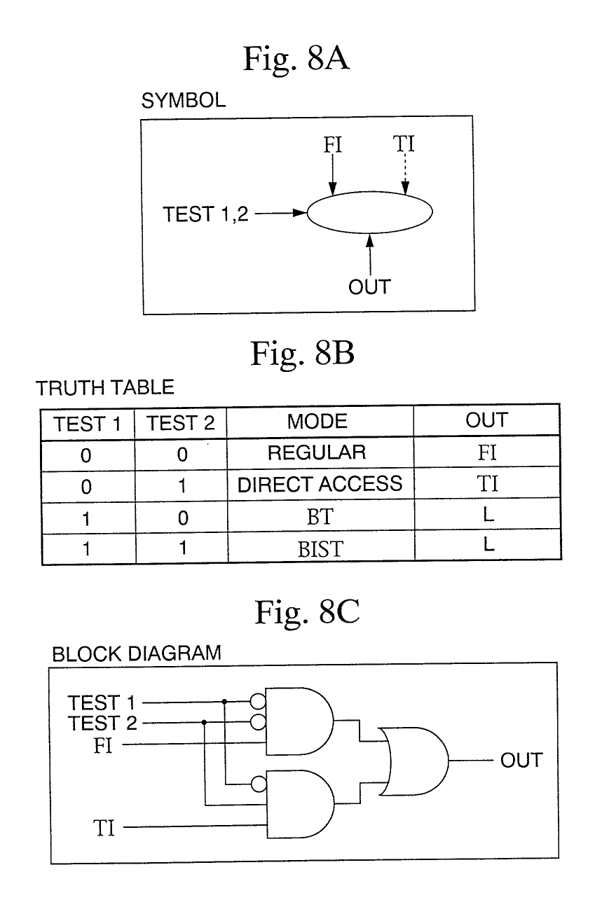

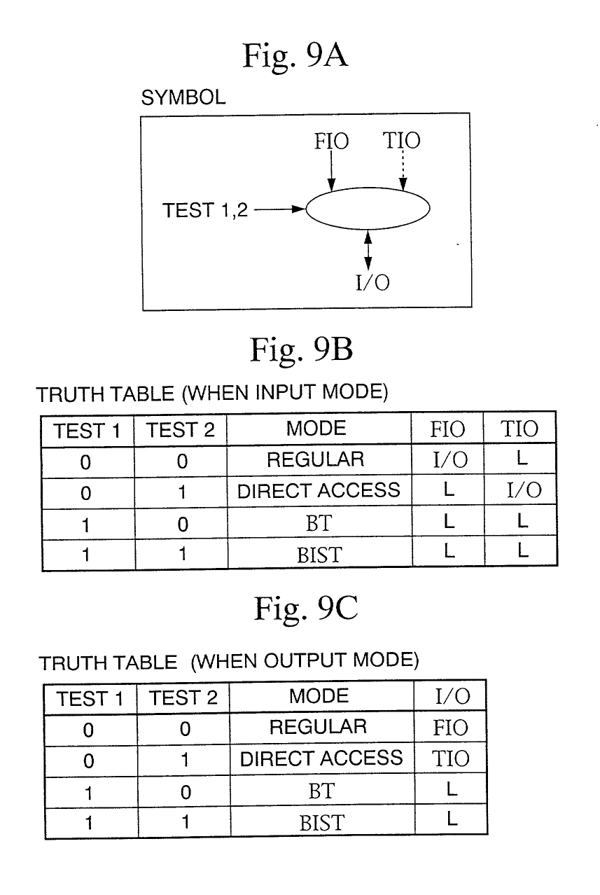

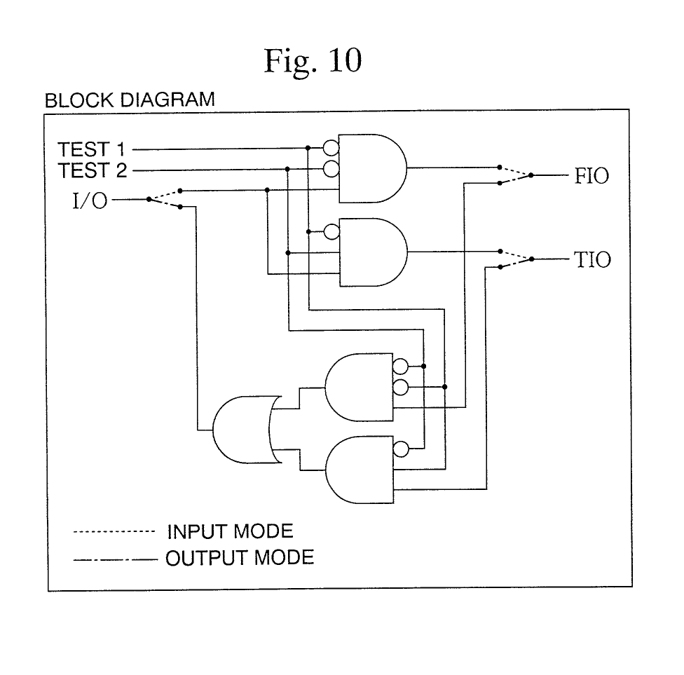

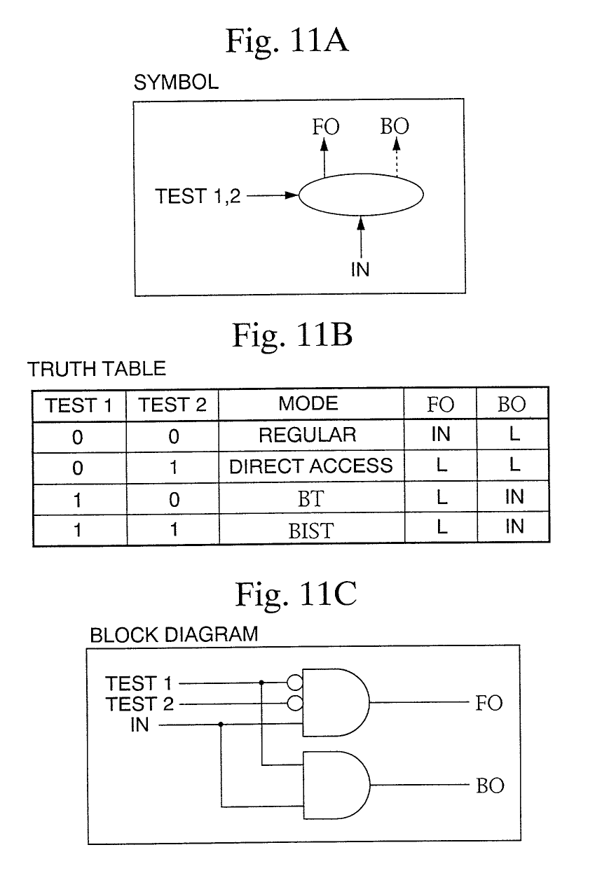

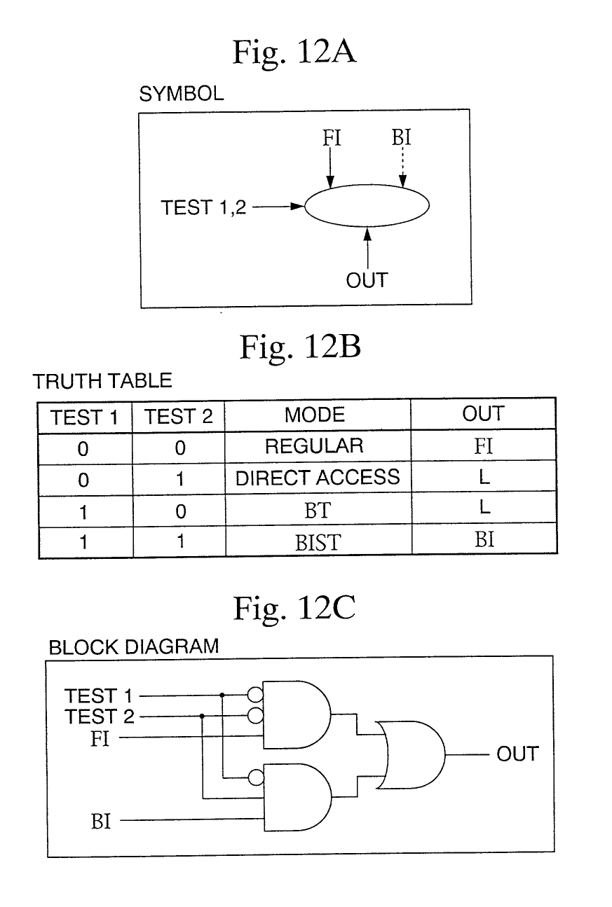

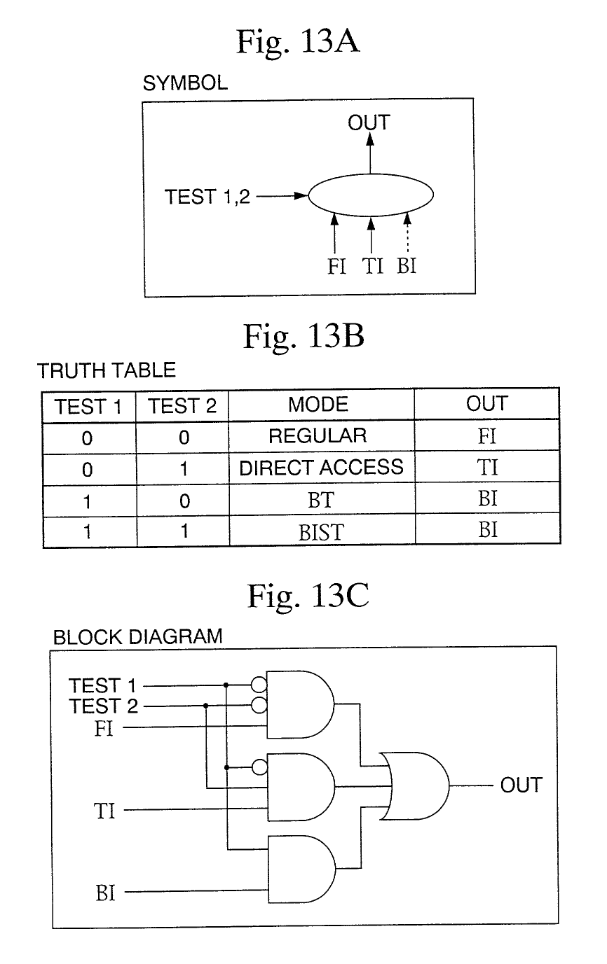

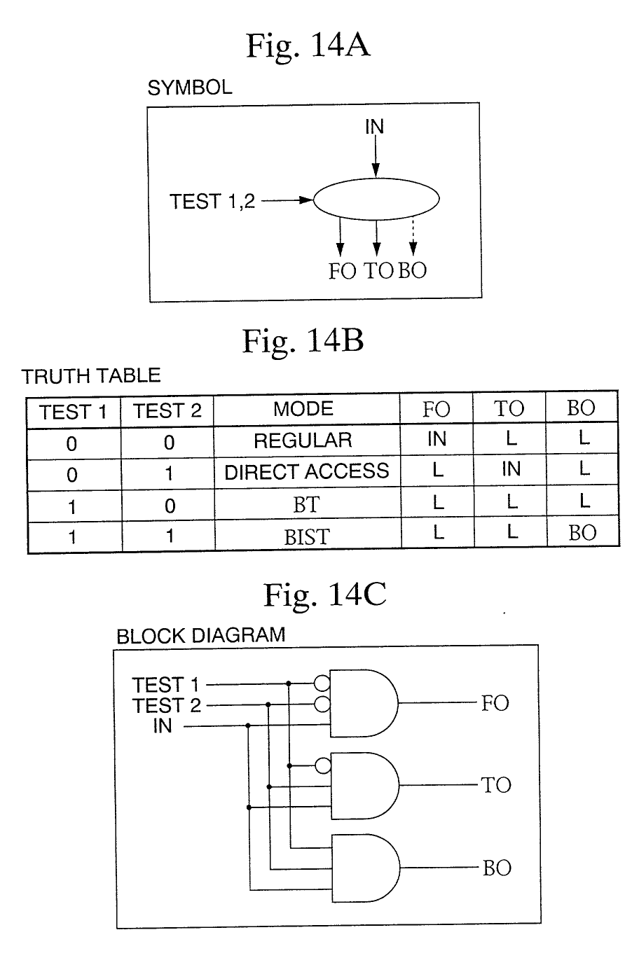

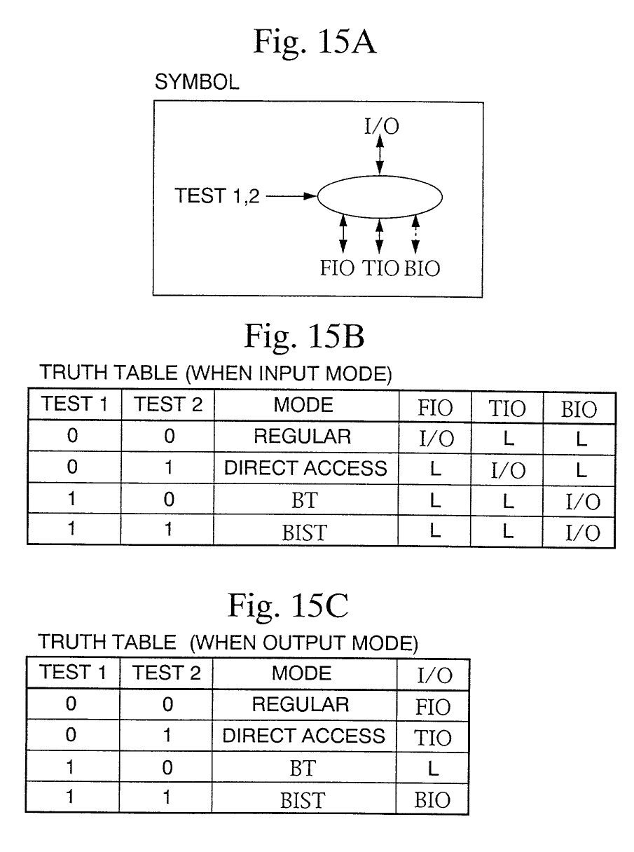

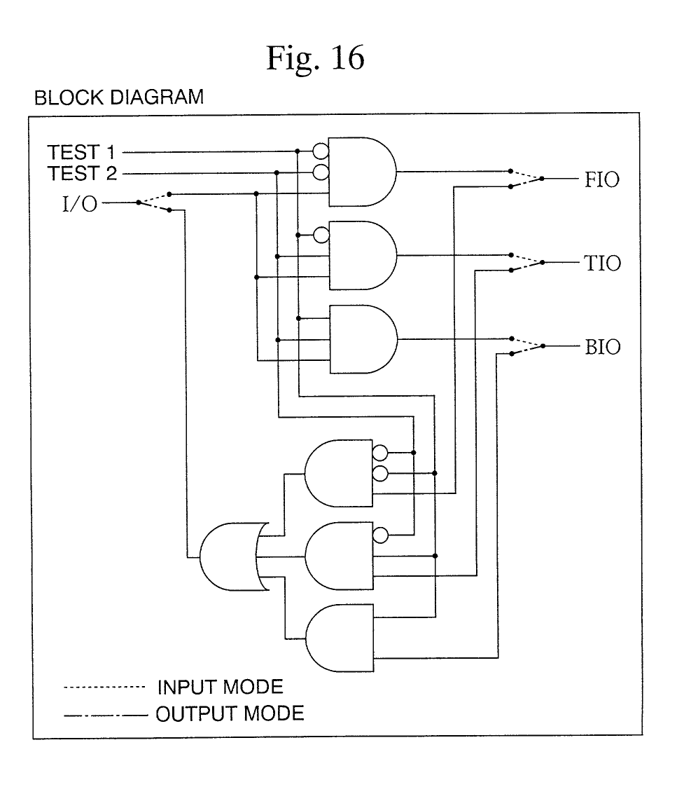

The specific structure of each selector used in the present embodiment is shown in FIGS. 7 through 16. Here, the TEST terminal is composed of two bits, and the two bits are referred to as TEST 1 and TEST 2. FIG. 7 shows the specific structure of selector 20, FIG. 8 shows the specific structure of selector 21, FIGS. 9 and 10 show the specific structure of selector 22, FIG. 11 shows the specific structure of selectors 7 and 8, FIG. 12 shows the specific structure of selector 16, FIG. 13 shows the specific structure of selector 5, FIG. 14 shows the specific structure of selector 18, and FIGS. 15 and 16 show the specific structure of selector 6.

An example where the built-in DRAM 3 is SDRAM (Synchronous dynamic random access memory) will now be described. Built into this SDRAM are a mode register and mode register automatic setting circuit 3e for automatically setting this mode register at the time of testing. When the system LSI 1 enters BT mode or BIST mode, the SDRAM mode register is automatically set to a predetermined value by the mode register automatic setting circuit 3e.

The characteristics of SDRAM will now be briefly described. The characteristics of SDRAM are (1) clock synchronized operation, (2) control by command, (3) control by mode register. Hereunder is a brief description of each.

(1) Clock Synchronized Operation

Each control signal is latched by the edge of the clock signal to input and output data synchronized to the clock signal.

(2) Control by Command

Command means the combination of control signal logic levels. Here, in the case where a conventional DRAM is controlled, control is also performed by the combination of control signal logic levels, however, there is no concept of command therein.

A conventional DRAM has a data terminal, an address terminal, a write terminal, and a read terminal, wherein, when assigning an address with the address terminal and activating the read terminal, data is output, and when assigning an address with the address terminal, applying data to be written to the data terminal and activating the write terminal, data is written.

On the other hand, with SDRAM, for example when a read command and an address command are input at a predetermined timing, data is output at the next predetermined timing.

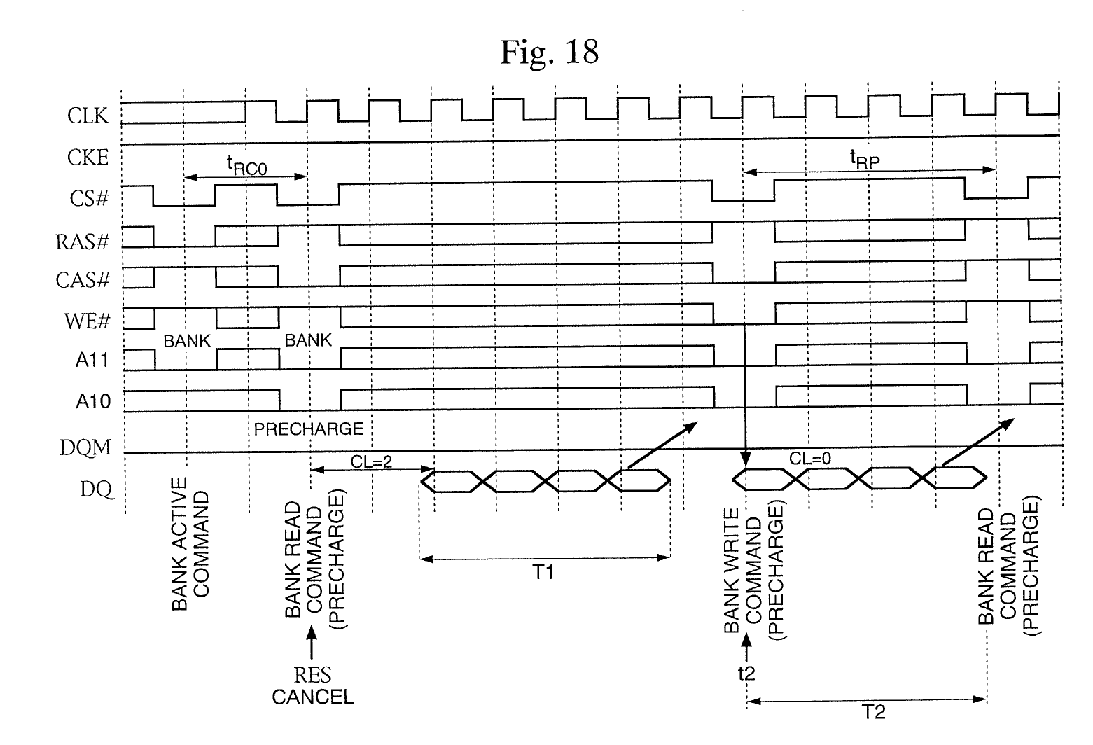

In the timing diagram of FIG. 18, after a read command is input at time t1, data for four addresses are output during the period T1. The duration of the output data is called the burst length. Also when writing, if a write command is input at time t2, data of the burst length is output during the period T2. These are the characteristics of SDRAM control. Here, the number of bits delay from after the command is input until the data is output is called the CAS latency. The SDRAM mode register sets the timing and length of input-output such as burst length and CAS latency.

(3) Control by Mode Register

The mode register is a register for determining how the SDRAM operates, in other words the operation mode. The mode register performs settings such as CAS latency and burst length. Once the setting has been done, the setting is maintained until it is either reset or the power is removed.

If the system LSI 1 has built-in SDRAM that has a mode register and a mode register automatic setting circuit 3e, the BT circuit 4 and the BIST circuit 15 can be simplified and miniaturized. This is because, when the system LSI 1 is set in BT mode or BIST mode, the value of the SDRAM mode register is automatically set by the mode register automatic setting circuit 3e, and hence the BT circuit 4 or the BIST circuit 15 does not need to generate a mode register setting command. In this manner, a circuit for generating a mode register setting command does not need to be provided for the BT circuit 4 or the BIST circuit 15, hence enabling simplification and miniaturization of the BT circuit 4 and the BIST circuit 15.

The operations for setting the SDRAM mode register will now be described. With SDRAM, immediately after the SDRAM is powered up, it is necessary to set the mode register to determine the operation mode of this SDRAM. Furthermore, it is necessary to set the mode register before writing data into SDRAM by the BT circuit 4, writing data into SDRAM by the BIST circuit 15, and reading out the data.

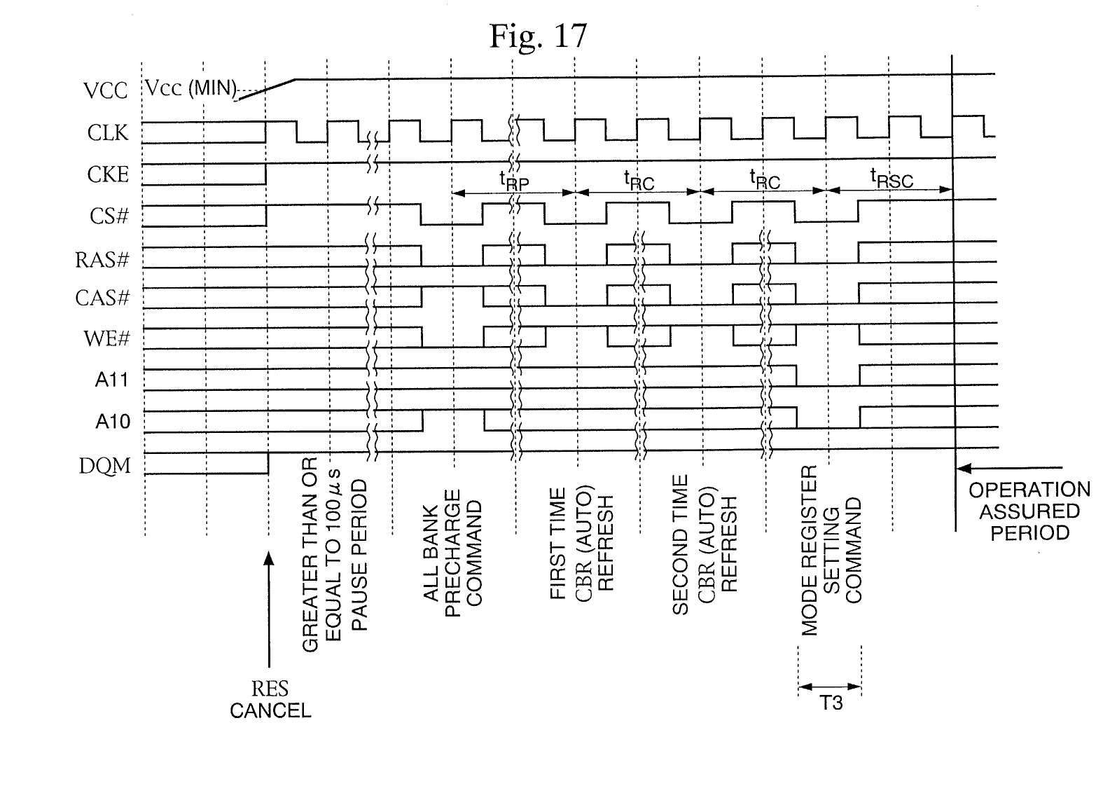

FIG. 17 and FIG. 18 show timing diagrams from powering up the system LSI 1 to writing and reading out data. FIG. 17 is a timing diagram of the initialization operation after power on, and FIG. 18 is a timing diagram of writing and reading out data after the initialization is completed. SDRAM, after the initialization shown in FIG. 17, performs operations of writing and reading out data, shown in FIG. 18. The mode register is set during the period T3 in FIG. 17 by a mode register setting command.

The mode register setting operation will now be described with reference to FIG. 17. Firstly, after the power voltage of the SDRAM is increased, reset is cancelled to initialize the SDRAM. Then, several predetermined commands are written into the mode register. One of them is the mode register setting command shown in period T3 in the figure.

After the initialization, if BIST is performed, writing and reading out data as shown in FIG. 18 are performed. If BT is performed, since no comparison of the written data and read out data is performed, only writing is performed using a write command.

Heretofore, a circuit for generating these commands has had to be built into the BT circuit 4 and the BIST circuit 15. However, since the BT circuit 4 and the BIST circuit 15 are only for testing, in other words for manufacturers of the system LSI 1, they are surplus circuits to users. Therefore, it is desirable to make them as small scale as possible.

Therefore, the present invention provides a mode register automatic setting circuit 3e inside the built-in DRAM 3 (SDRAM), and the arrangement is such that, when BT mode or BIST mode is used, without any command transmission, test mode is automatically entered. In this way a command generation circuit does not need to be built into the BT circuit 4 and the BIST circuit 15, hence enabling the BT circuit 4 and the BIST circuit 15 to be simplified and miniaturized.

Since the command generation circuit for setting this test mode by generating patterns is a circuit in which a lot of counters are used, the circuit scale increases, so that the test circuit that the user (manufacturer) does not use becomes large, which is not desirable.

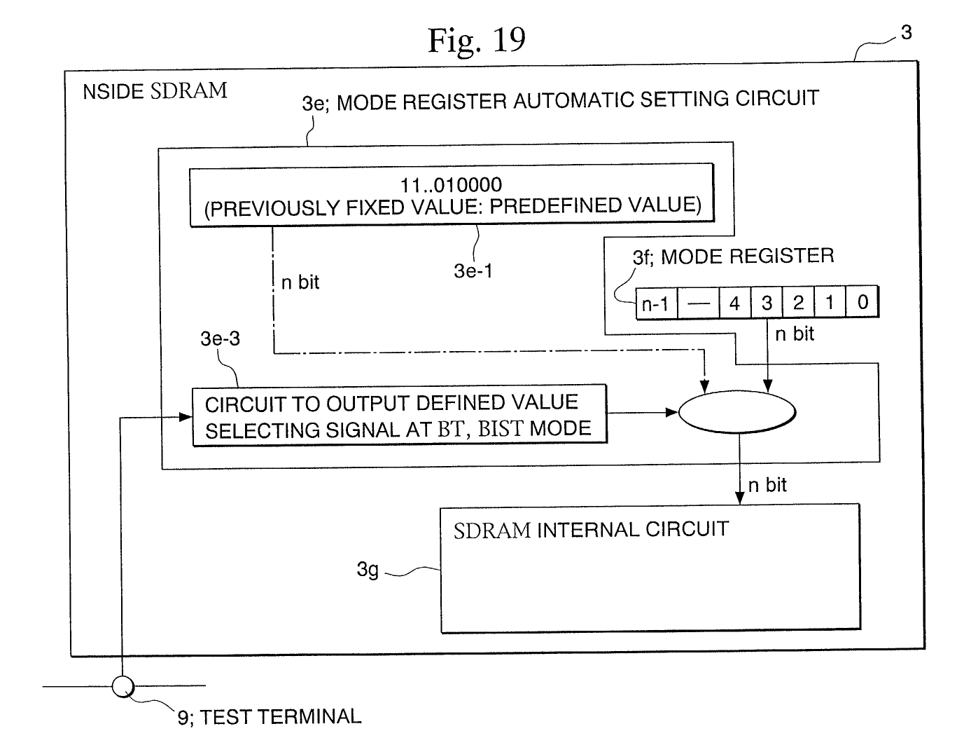

The structure of the built-in DRAM 3 (SDRAM) that the mode register automatic setting circuit 3e of the present invention is built into will now be described with reference to FIG. 19. The built-in DRAM 3 has a mode register automatic setting circuit 3e, a mode register 3f and an SDRAM internal circuit 3g. The mode register automatic setting circuit 3e has a predefined value output circuit 3e-1 for outputting a predefined value at testing of the system LSI 1, a selector 3e-2 for selecting either the output of this predefined value output circuit 3e-1, or the output of the mode register 3f, and a selector control circuit 3e-3 that inputs a mode signal from the TEST terminal 9 of the system LSI 1, and controls the selector 3e-2 based on this input.

When a mode signal indicating BT mode or BIST mode is input from the TEST terminal 9, the selector control circuit 3e-3 that inputs this mode signal switches the selector 3e-2 to the predefined value output circuit 3e-1 side. Then, the output from the predefined value output circuit 3e-1 is input to the SDRAM internal circuit 3g instead of the output from the mode register 3f. The output of the predefined value output circuit 3e-1 is previously loaded with the commands needed to set the SDRAM in test mode.

The predefined value output circuit 3e- 1 is a circuit for setting the lines corresponding to each bit of the mode register 3f to H or L, and the circuit scale is small. The selector 3e-2 is arranged such that the output of this predefined value output circuit 3e-1 and the output of the mode register 3f can be switched by the mode setting of the TEST terminal 9 of the system LSI 1. When the setting of the TEST terminal 9 is BT mode or BIST mode, this selector 3e-2 is switched to the predefined value output circuit 3e-1 that sets the level of each bit to set test mode automatically.

Accordingly, when in BT mode or BIST mode, the built-in DRAM 3 (SDRAM) is automatically set to test mode. Therefore, it is not necessary to provide a circuit for generating the mode register setting command in the BT circuit 4 and the BIST circuit 15, hence enabling the BT circuit 4 and the BIST circuit 15 to be simplified and miniaturized.

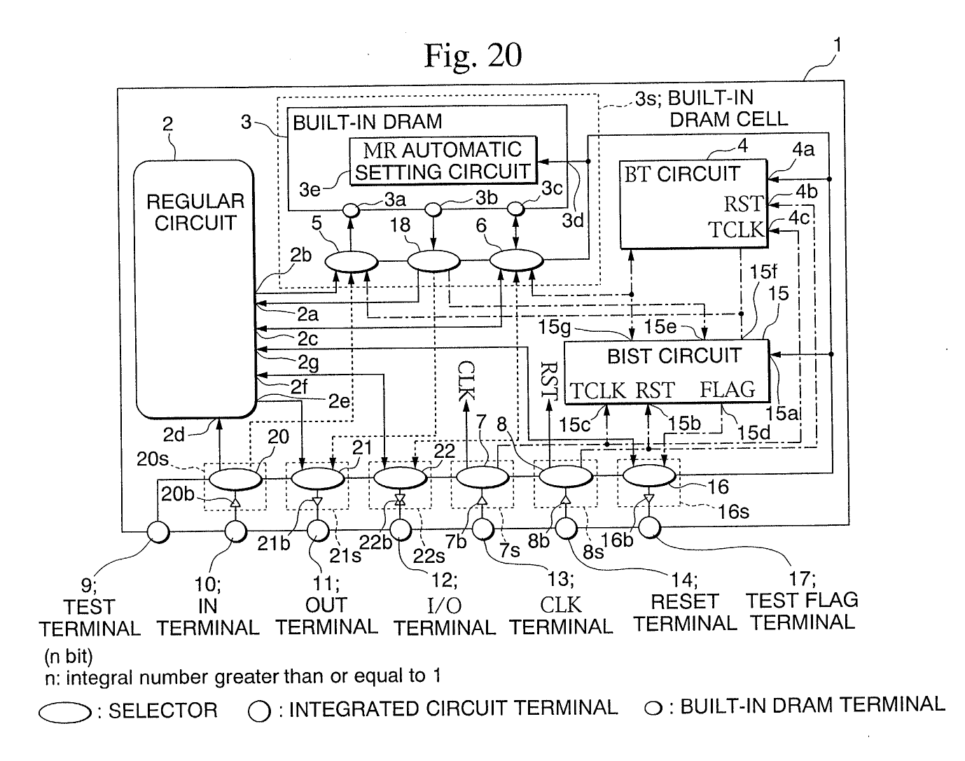

FIG. 20 is a block diagram of a system LSI that has DRAM built in, being a seventh embodiment of the present invention. In the system LSI 1, selectors 20, 21, 22, 7, 8 and 16 connected to the external terminals of this system LSI 1 are built into I/O cells 20s, 21s, 22s, 7s, 8s and 16s, and selectors 5, 18 and 6 connected to the terminals of the built-in DRAM 3 are built into the built-in DRAM cell 3s.

The I/O cell 20s has an input buffer 20b built in, the I/O cell 21s has an output buffer 21b built in, the I/O cell 22s has an input-output buffer 22b built in, the I/O cell 7s has an input buffer 7b built in, the I/O cell 8s has an input buffer 8b built in, and the I/O cell 16s has an output buffer 16b built in.

If the abovementioned I/O cells and built-in DRAM cell 3s are used when a manufacturer designs a circuit part for performing regular operations, selectors are included in the circuit from the beginning of the design. In this way, after designing the circuit part for performing regular operation, even if a semiconductor maker adds a testing circuit, the signal path of the circuit part for performing regular operation does not need to be changed. Consequently, addition of a testing circuit does not change the timing of the circuit for performing regular operations.

The detail of adding a testing circuit, wherein timing (time delay) does not change, in other words, the BT circuit 4 and the BIST circuit 15 and the like, will now be described again.

Currently, a semiconductor integrated circuit, in particular, a digital semiconductor integrated circuit is often designed from a cell base. Cell base is a system in which small sized circuits to be used inside a semiconductor integrated circuit, such as inverters, AND gates, OR gates, and flip flops, circuit blocks such as adders, macros such as CPU and memory, and I/O components such as input buffers and output buffers, are defined as cells in a circuit database (library), and these cells are combined to design a semiconductor integrated circuit.

A semiconductor integrated circuit to be designed by cell base is also called a cell base IC. Each cell to be used in the cell base IC has inputs and outputs, signal propagation time from input to output, and time delay for signal propagation with loads connected to the outputs defined. Generally, a circuit designer (manufacturer) designs a semiconductor integrated circuit with consideration of these time delays, that is to say, while performing delay design.

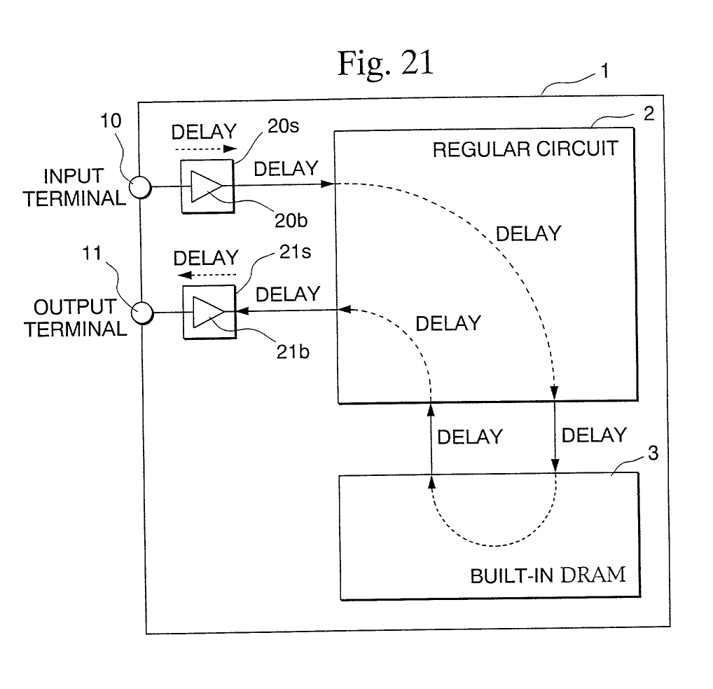

FIG. 21 is a conceptual diagram of the delay design. To design the circuit, the circuit designer (manufacturer) considers delay of the I/O cell 20s and delay that occurs inside the regular circuit 2 (delay shown by broken lines in the figure), and delay of a signal line connecting the I/O cell 20s and the regular circuit 2 and delay of the signal lines connecting the regular circuit 2 and the built-in DRAM 3 (delay shown by full lines in the figure).

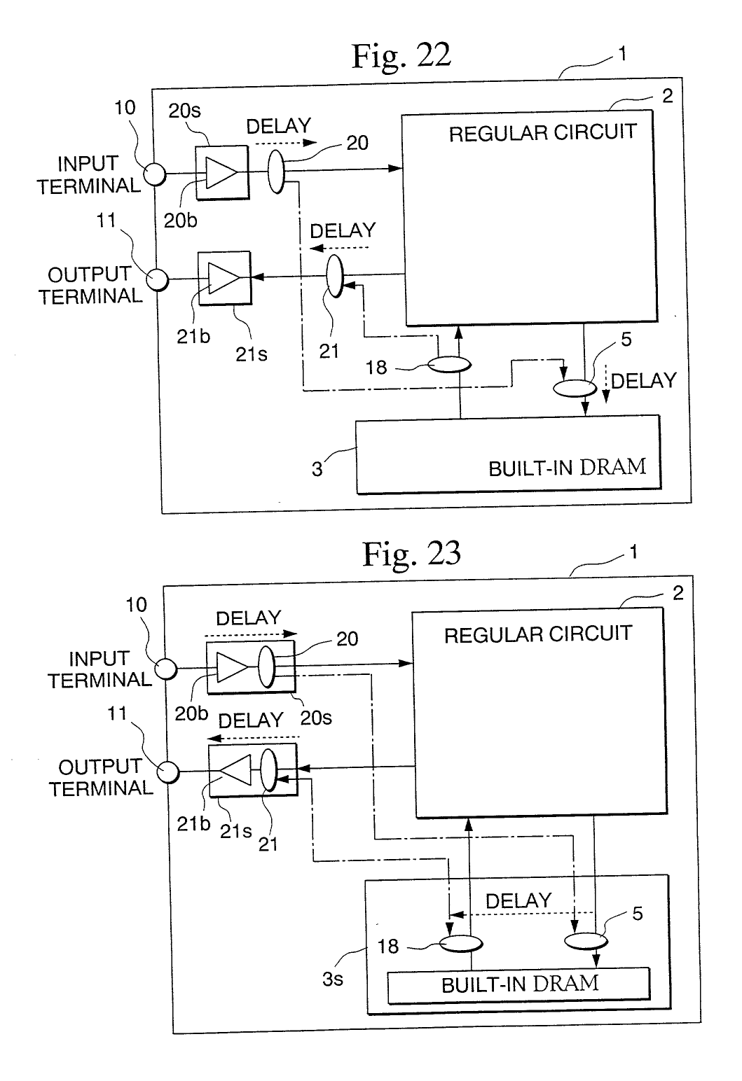

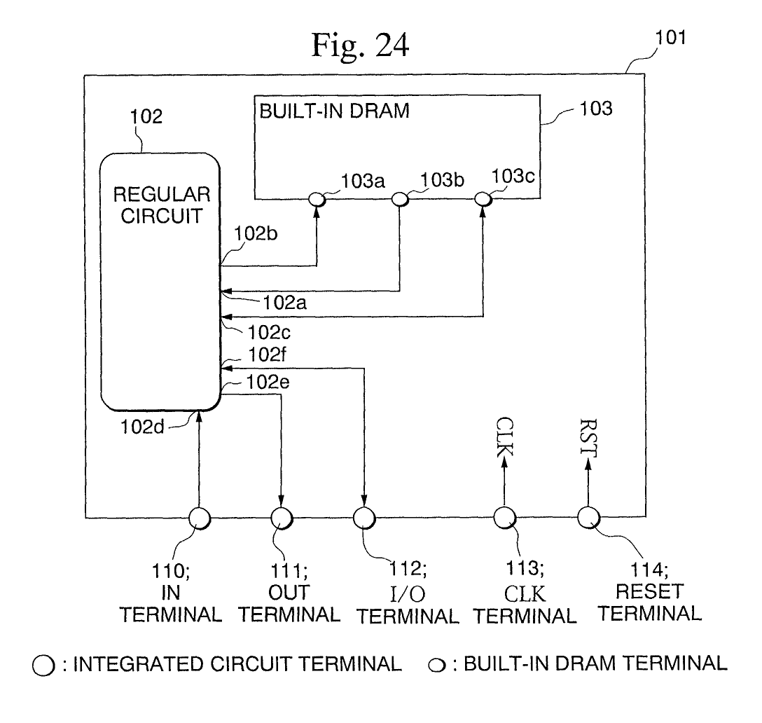

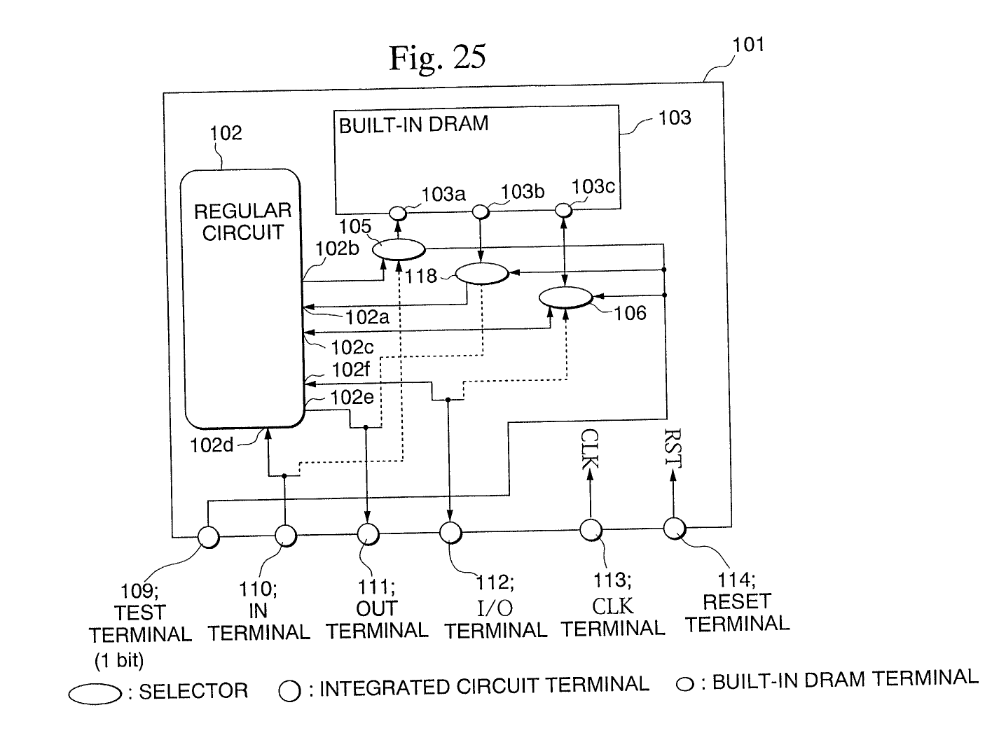

FIG. 22 is a conceptual diagram in which test circuits including selectors 20, 21, 18 and 5 are added to a circuit where the circuit design for regular operating conditions is completed by conventional techniques. With conventional techniques, since the selectors are added to the circuit after delay design has been performed, delays (delay shown by broken lines in the figure) of the selectors 20, 21, 18 and 5 are added to the delay of the circuit in regular operating conditions, which had already been established once. Therefore, the delay design needs to be done over again.

With the present invention, to solve the abovementioned problems, as shown in FIG. 23, the arrangement is such that the selectors 20, 21, 18 and 5 are built into the I/O cell 20s and the built-in DRAM cell 3s to define the delay time of the cells including the delay time of the selectors. In this way, without changing the circuit and wiring of the regular operating conditions, it is possible to add a test circuit. Therefore, delay design does not need to be done over again after adding the test circuit. Here, the test circuit is all that is required for testing, that is to say, the BT circuit 4, the BIST circuit 15 and the selectors.

The design procedure of the system LSI will now be described. The system LSI, being a custom item, is often jointly designed by a semiconductor maker and a manufacturer who uses the system LSI as a component to manufacture products such as electric products. At the time, the manufacturer designs the circuit for the part that operates under normal conditions, and the semiconductor maker designs the test circuit. This is because test is performed by the semiconductor maker when the system LSI is shipped to the manufacturer.

Accordingly, the manufacturer's side designs a circuit as shown in FIG. 21. However, with the development and minuteness of the degree of integration of semiconductor integrated circuits, it is becoming difficult to design the delays (timing) of the circuit.

At this time, the semiconductor maker's side inserts a test circuit into a circuit in which timing design has already been completed by the manufacturer's side. Since the regular input and output terminals and the terminals for testing are also used as the external terminals, selectors are used. Then, new delays appear in the selectors, which wrecks the timing designed by the manufacturer's side. When previously satisfactory timing is wrecked, the timing needs to be redesigned again, or there may be a case where timing design is impossible.

Therefore, as shown in FIG. 23, the selector 20 is built into the I/O cell 20s, the selector 21 is built into the I/O cell 21s, and the selectors 18 and 5 are built into the built-in DRAM cell 3s. Then the manufacturer's side designs only the parts of the regular operation circuit shown with the solid lines in the figure, assuming from the beginning that there are delays in the selectors. As a result, the semiconductor maker's side can add the lines of the test circuit shown by alternate long and short dashed lines, without changing the amount of delay of the regular operation circuit along with the solid lines. That is to say, a test circuit can be added without changing the amount of delay that the manufacturer's side had expected.

With the present invention, since a burn-in test circuit is built into a semiconductor integrated circuit, dynamic BT test of the built-in memory can be carried out by a clocked BT system that outputs only simple control signals, in other words, a clock signal and a reset signal. Hence it is not necessary to install a new and expensive dynamic BT system in a semiconductor integrated circuit manufacturing line.

This is because, if the clock signal and the reset signal are supplied from the clocked BT system to the burn-in test circuit built into the semiconductor integrated circuit, the burn-in test circuit can generate the complex patterns required for dynamic BT.

Furthermore, with the present invention, since a built-in self test circuit is built into the semiconductor integrated circuit, this built-in self test circuit generates test patterns for functional test (LFT; Loose Function Test) of the built-in memory. Consequently, with wafer test of the semiconductor integrated circuit, since the memory can be tested using a logic circuit tester, a memory tester is not required. Therefore, for wafer test of the semiconductor integrated circuit, two processes, being a logic circuit test process by a logic circuit tester and a memory test process by a memory tester, do not need to be installed, hence enabling the wafer test process to be simplified.

Moreover, with the present invention, since first selectors and second selectors are built into the semiconductor integrated circuit, by changing the selectors it is possible to access the built-in memory directly from the external terminals, so that the same test as for general memory can be performed for the built-in memory. Furthermore, at the time of testing the built-in memory, it is possible to completely disconnect the connection between the external terminals of the semiconductor integrated circuit and the logic circuit (regular circuit) using the first selectors, hence enabling an exact test of the built-in memory, for example an accurate measurement of power consumption of the built-in memory.

Moreover, if the built-in memory is SDRAM, and this SDRAM has a mode register and a mode register automatic setting circuit built in, at the time of testing the semiconductor integrated circuit the mode register of SDRAM is automatically set by the mode register automatic setting circuit, and hence the burn-in test circuit or the built-in self set circuit does not need to generate mode register setting commands. Consequently, there is no need to install a circuit for generating mode register setting commands inside the burn-in test circuit or the built-in self test circuit, so that the burn-in test circuit or the built-in self test circuit can be simplified and miniaturized.

Furthermore, with the present invention, since the first selectors are built into the I/O cells, and the second selectors are built into the built-in memory cells, then even if a test circuit is added after designing the circuit to perform regular operations, timing of the circuit to perform regular operation does not change.

What is claimed is:

1. A semiconductor integrated circuit having;
a logic circuit connected to external terminals,
built-in memory connected to this logic circuit, and
a burn-in test circuit for, when performing burn-in test, writing predetermined data into said built-in memory.

2. A semiconductor integrated circuit having;
a logic circuit connected to external terminals,
built-in memory connected to this logic circuit, and
a built-in self test circuit for, when performing built-in self test of this built-in memory, writing predetermined data into said built-in memory, reading out the written data from said built-in memory, comparing the written data with the read out data, and judging whether said built-in memory is normal.

3. A semiconductor integrated circuit having,
a logic circuit connected to external terminals,
built-in memory connected to this logic circuit,
a burn-in test circuit for, when performing burn-in test of said built-in memory, writing predetermined data into said built-in memory, and
a built-in self test circuit for, when performing built-in self test of said built-in memory, writing predetermined data into said built-in memory, reading out the written data from said built-in memory, comparing the written data with the read out data, and judging whether said built-in memory is normal.

4. A semiconductor integrated circuit according to claim 3, wherein said burn-in test circuit and built-in self-test circuit are formed inside one test circuit cell.

5. A semiconductor integrated circuit having;
a logic circuit connected to external terminals via a first selector, and built-in memory connected to this logic circuit via a second selector, wherein;
said first selector selects whether to connect the external terminals to the logic circuit or to connect to the second selector, and
said second selector selects whether to connect the built-in memory either to the logic circuit or to the first selector.

6. A semiconductor integrated circuit according to claim 5, having a burn-in test circuit for, when performing burn-in test of said built-in memory, writing predetermined data into said built-in memory.

7. A semiconductor integrated circuit according to claim 5, having a built-in self test circuit for, when performing built-in self test for said built-in memory, writing predetermined data into said built-in memory, reading out the written data from said built-in memory, comparing the written data with the read out data, and judging whether said built-in memory is normal.

8. A semiconductor integrated circuit according to claim 5, having;
a burn-in test circuit for, when performing burn-in test of said built-in memory, writing predetermined data into said built-in memory, and
a built-in self test circuit for, when performing built-in self test of said built-in memory, writing predetermined data into said built-in memory, reading out the written data from said built-in memory, comparing the written data with the read out data, and judging whether said built-in memory is normal.

9. A semiconductor integrated circuit according to any one of claim 1 to claim 8, wherein said built-in memory is DRAM.

10. A semiconductor integrated circuit according to claim 9, wherein
said DRAM is SDRAM, and
this SDRAM has built-in,
a mode register for setting the operation mode of this SDRAM and
a mode register automatic setting circuit for automatically setting said mode register corresponding to an input from the external terminals.

11. A semiconductor integrated circuit according to any one of claim 5 to claim 8, wherein said first selector, and an input buffer or an output buffer connected to the external terminals are contained in an I/O cell, and
said second selector and said built-in memory are contained in a built-in memory cell.

12. A semiconductor integrated circuit manufacturing method, wherein an I/O cell and a built-in memory cell according to claim 11 are used in the design.

13. A semiconductor integrated circuit test method, wherein a semiconductor integrated circuit according to any one of claim 1 to claim 11 is used.

14. A semiconductor integrated circuit manufacturing method, wherein a test method according to claim 13 is used.
